(19) United States
(12) Patent Application Publication
(10) Pub. No.: US 2026/0018403 A1
(43) Pub. Date: Jan. 15, 2026

(54) FILM FORMING METHOD AND SUBSTRATE PROCESSING APPARATUS

(71) Applicant: Tokyo Electron Limited, Tokyo (JP)

(72) Inventors: Hiroki MURAKAMI, Nirasaki City (JP); Shuichiro SAKAI, Nirasaki City (JP)

(21) Appl. No.: 19/336,566

(22) Filed: Sep. 23, 2025

Related U.S. Application Data
(63) Continuation of application No. PCT/JP2024/011638, filed on Mar. 25, 2024.

(30) Foreign Application Priority Data
Mar. 31, 2023 (JP) 2023-057931

(51) Int. Cl. H01L 21/02; C23C 16/455; C23C 16/52

(52) U.S. Cl. CPC H01L 21/02164; C23C 16/45523; C23C 16/52; H01L 21/02274; H01L 21/0228

(57) ABSTRACT

A film forming method of forming an oxide film, which contains at least a predetermined element and oxygen, on a substrate, includes: (a) supplying a first raw material gas, which contains the predetermined element, to the substrate; (b) supplying a second raw material gas, which contains the predetermined element, contains a bond between the predetermined element and oxygen and a bond between the predetermined element and a hydroxyl group, and is different from the first raw material gas, to the substrate; and (c) repeating one cycle a plurality of times, the one cycle including (a) and (b).

### CROSS-REFERENCE TO RELATED APPLICATION

This application is a bypass continuation application of International Patent Application No. PCT/JP2024/011638 having an international filing date of Mar. 25, 2024 and designating the United States, the international application being based upon and claiming the benefit of priority from Japanese Patent Application No. 2023-057931, filed on Mar. 31, 2023, the entire contents of which are incorporated herein by reference.

### TECHNICAL FIELD

The present disclosure relates to a film forming method and a substrate processing apparatus.

### BACKGROUND

Patent Document 1 discloses a method of forming a silica layer on a substrate, the method including exposing a heated substrate including a region containing a metal or semimetal compound having Lewis acid properties to silanol vapor to form a silica layer having a thickness of more than 2 nm on the acidic region of the substrate.

Patent Document 2 discloses a method of forming a silicon oxide film, the method being characterized in that it includes an adsorption step of supplying monovalent aminosilane into a reaction chamber accommodating a workpiece to adsorb silicon on the workpiece, and a silicon oxide film forming step of supplying an activated oxidizing gas to the silicon adsorbed in the adsorption step to oxidize the silicon, thereby forming a silicon oxide film on the workpiece, the adsorption step and the silicon oxide film forming step being repeated a plurality of times.

### PRIOR ART DOCUMENTS

### Patent Documents

Patent Document 1: Japanese National Publication of International Patent Application No. 2005-521792

Patent Document 2: Japanese Laid-Open Patent Publication No. 2012-28741

### SUMMARY

According to one embodiment of the present disclosure, there is provided a film forming method of forming an oxide film, which contains at least a predetermined element and oxygen, on a substrate, including: (a) supplying a first raw material gas, which contains the predetermined element, to the substrate; (b) supplying a second raw material gas, which contains the predetermined element, contains a bond between the predetermined element and oxygen and a bond between the predetermined element and a hydroxyl group, and is different from the first raw material gas, to the substrate; and (c) repeating one cycle a plurality of times, the one cycle including (a) and (b).

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram showing an example of a configuration of a substrate processing apparatus according to a first embodiment.

FIG. 2 is a time chart showing an example of a film forming process according to the first embodiment.

FIG. 3A is a schematic diagram showing an example of a state of a substrate surface in the film forming process according to the first embodiment.

FIG. 3B is a schematic diagram showing an example of a state of the substrate surface in the film forming process according to the first embodiment.

FIG. 3C is a schematic diagram showing an example of a state of the substrate surface in the film forming process according to the first embodiment.

FIG. 4 is a graph showing an example of a film formation rate and in-plane uniformity of a film thickness with respect to temperature and pressure.

FIG. 5 is a graph showing an example of a film thickness and in-plane uniformity of the film thickness with respect to the number of cycles.

FIG. 6A is a time chart showing an example of a film forming process.

FIG. 6B is a time chart showing an example of a film forming process.

FIG. 6C is a time chart showing an example of a film forming process.

FIG. 6D is a time chart showing an example of a film forming process.

FIG. 7 is a graph showing an example of a film increase amount of a SiO2 film in each film forming process.

FIG. 8 is a graph showing an example of a film increase rate of the SiO2 film in each film forming process.

FIG. 9 is a time chart showing an example of a film forming process according to a second embodiment.

FIG. 10 is a graph showing an example of a film formation rate.

FIG. 11 is a graph showing an example of a wet etching rate and shrinkage due to heat treatment.

FIG. 12 is a schematic diagram showing an example of a configuration of a substrate processing apparatus according to a third embodiment.

FIG. 13 is a time chart showing an example of a film forming process according to the third embodiment.

FIG. 14A is a schematic diagram showing an example of a state of a substrate surface in the film forming process according to the third embodiment.

FIG. 14B is a schematic diagram showing an example of a state of the substrate surface in the film forming process according to the third embodiment.

FIG. 14C is a schematic diagram showing an example of a state of the substrate surface in the film forming process according to the third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments for carrying out the present disclosure are described with reference to the drawings. Throughout the drawings, the same components are denoted by the same reference numerals, and explanation thereof may not be repeated.

### Substrate Processing Apparatus

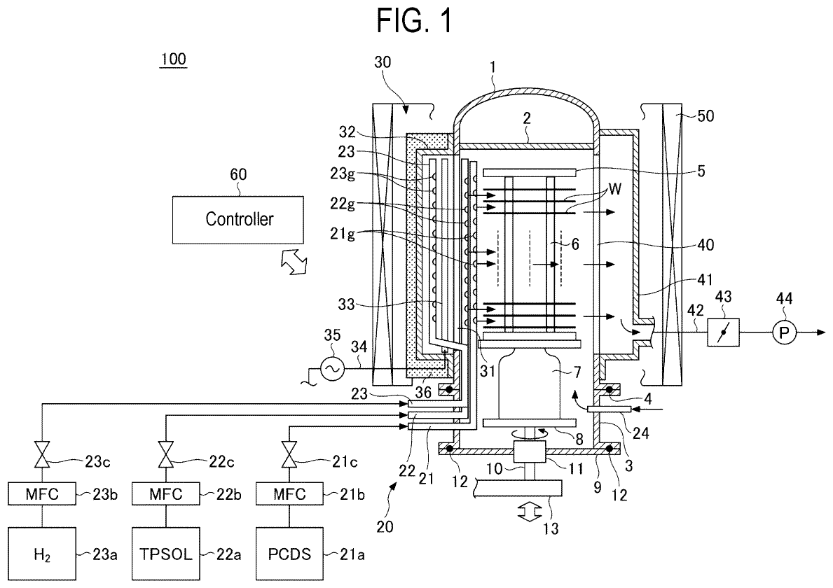

A substrate processing apparatus 100 according to a first embodiment is described with reference to FIG. 1. FIG. 1 is a schematic diagram showing an example of a configuration of the substrate processing apparatus 100 according to the first embodiment. The substrate processing apparatus 100 is a film forming apparatus that forms an oxide film, containing at least a predetermined element and oxygen (O), on a substrate W. Herein, the predetermined element includes at least one selected from the group of silicon (Si) and a metal element (e.g., Ge, B, Al, Hf, Zr, Ta, La, Ti, etc.). That is, the substrate processing apparatus 100 is a film forming apparatus that forms a silicon oxide film or a metal oxide film on the substrate W. In addition, the oxide film may contain other elements, such as carbon (C), nitrogen (N), etc. In the following description, an example is described in which the predetermined element is silicon (Si) and the oxide film formed on the substrate is a silicon oxide film (SiO₂).

The substrate processing apparatus 100 includes a cylindrical processing container 1 with a ceiling and an open lower end. The entire processing container 1 is made of, for example, quartz. A ceiling plate 2 made of quartz is provided near an upper end of the processing container 1, and a region below the ceiling plate 2 is sealed. A cylindrical metal manifold 3 is connected to an opening at the lower end of the processing container 1 via a seal member 4 such as an O-ring.

The manifold 3 supports the lower end of the processing container 1, and a wafer boat (substrate support) 5 on which a plurality of semiconductor wafers (for example, 25 to 150 semiconductor wafers) (hereinafter referred to as “substrates W”) are placed in multiple stages as substrates is inserted into the processing container 1 from below the manifold 3. In this manner, the substrates W are accommodated substantially horizontally in the processing container 1 with intervals in a vertical direction. The wafer boat 5 is made of, for example, quartz. The wafer boat 5 includes three rods 6 (two rods shown in FIG. 1), and the substrates W are supported by grooves (not shown) formed on the rods 6.

The wafer boat 5 is placed on a table 8 via a heat-insulating tube 7 made of quartz. The table 8 is supported on a rotary shaft 10 that penetrates a metal (stainless steel) lid 9 that opens/closes the opening at the lower end of the manifold 3.

A magnetic fluid seal 11 is provided at a penetration portion of the rotary shaft 10, thus hermetically sealing the rotary shaft 10 while supporting the rotary shaft 10 rotatably. A seal member 12 is provided between a periphery of the lid 9 and the lower end of the manifold 3 in order to maintain airtightness inside the processing container 1.

The rotary shaft 10 is installed at a tip of an arm 13 supported by a lift (not shown) such as a boat elevator, and the wafer boat 5 and the lid 9 are raised/lowered as a unit and inserted into/removed from the processing container 1. The table 8 may be fixed to the lid 9 side so that the substrate W is processed without rotating the wafer boat 5.

The substrate processing apparatus 100 also includes a gas supply 20 that supplies a predetermined gas such as a process gas or a purge gas into the processing container 1.

The gas supply 20 includes gas supply pipes 21 to 24. The gas supply pipes 21, 22, and 23 are made of, for example, quartz, and extend vertically after penetrating a sidewall of the manifold 3 inward and bending upward. Gas holes 21g, 22g, and 23g are formed at predetermined intervals in vertical portions of the gas supply pipes 21, 22, and 23 over a vertical length corresponding to a wafer support range of the wafer boat 5. Each of the gas holes 21g, 22g, and 23g ejects a gas in a horizontal direction. The gas supply pipe 24 is made of, for example, quartz and is formed by a short quartz pipe that penetrates the sidewall of the manifold 3.

The gas supply pipe (first raw material gas supply) 21 has its vertical portion (the vertical portion where the gas holes 21g are formed) provided inside the processing container 1. A first raw material gas is supplied to the gas supply pipe 21 from a gas supply source 21a via a gas pipe. A flow rate controller 21b and an opening/closing valve 21c are provided at the gas pipe. Thus, the first raw material gas from the gas supply source 21a is supplied into the processing container 1 via the gas pipe and the gas supply pipe 21.

The gas supply source 21a supplies the first raw material gas containing a predetermined element (e.g., Si). Herein, the first raw material gas contains a functional group that is highly reactive with at least one selected from the group of a terminal group (e.g., —OH, —NH, —Cl, —H, etc.) and a dangling bond (-(D/B)) formed on a substrate surface. The first raw material gas also contains at least one selected from the group of a bond (Si—H) between a predetermined element and hydrogen (H), a bond (Si—Cl) between a predetermined element and a halogen element (e.g., Cl), and a bond (Si—N) between a predetermined element and nitrogen (N). Specifically, when the predetermined element is silicon (Si), the first raw material gas includes at least one selected from the group of a silane-based gas, a chlorosilane-based gas, and a silylamine-based gas.

In the following description, an example is described in which the first raw material gas is a chlorosilane-based gas. In addition, inorganic halides such as SiCl₄, Si₂Cl₆, SiHCl₃, SiH₂Cl₂, SiH₃Cl, and Si₂HCl₅ may be suitably used as the first raw material gas. Specifically, an example is described in which the first raw material gas is PCDS (Pentachlorodisilane). The chemical formula of PCDS is shown below.

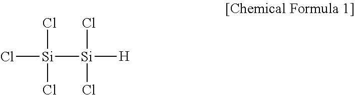

The gas supply pipe (second raw material gas supply) 22 has its vertical portion (the vertical portion where the gas holes 22g are formed) provided inside the processing container 1. A second raw material gas is supplied to the gas supply pipe 22 from a gas supply source 22a via a gas pipe. A flow rate controller 22b and an opening/closing valve 22c are provided at the gas pipe. Thus, the second raw material gas from the gas supply source 22a is supplied into the processing container 1 via the gas pipe and the gas supply pipe 22.

The gas supply source 22a supplies the second raw material gas, which contains a predetermined element (e.g., Si), contains a bond (Si—O) between the predetermined element and oxygen (O) and a bond (Si—OH) between the predetermined element and a hydroxyl group (—OH), and is different from the first raw material gas. When the predetermined element is silicon (Si), the second raw material gas contains a silanol-based gas. In addition, organic silanol may be suitably used as the second raw material gas.

In the following description, an example is described in which the second raw material gas is TPSOL (Tris(tert-pentoxy)silanol). The chemical formula of TPSOL is shown below.

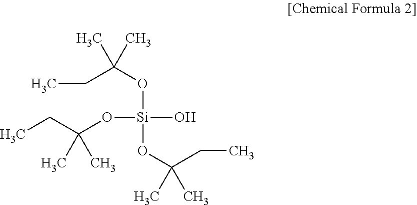 [SMILES: CCC(C)(C)O[Si](O)(OC(C)(C)CC)OC(C)(C)CC]

The gas supply pipe (modifying gas supply part) 23 has its vertical portion (the vertical portion where the gas holes 23g are formed) provided in a plasma generation space to be described later. A modifying gas is supplied to the gas supply pipe 23 from a gas supply source 23a via a gas pipe. A flow rate controller 23b and an opening/closing valve 23c are provided at the gas pipe. Thus, the modifying gas from the gas supply source 23a is supplied to the plasma generation space via the gas pipe and the gas supply pipe 23 and is turned into plasma in the plasma generation space, and active species (ions, radicals, etc.) of the modifying gas are supplied into the processing container 1.

The gas supply source 23a supplies the modifying gas. The modifying gas includes at least one selected from the group of a hydrogen-containing gas, an oxygen-containing gas, and a nitrogen-containing gas. Specifically, it is possible to use gases such as hydrogen (H₂) gas, oxygen (O₂) gas, a mixed gas of hydrogen and oxygen, water (H₂O), and an NH₃ gas.

In addition, the substrate processing apparatus 100 has been described as a plasma processing apparatus that generates plasma of the modifying gas and supplies the plasma to the substrate W in the processing container 1, but is not limited thereto. The substrate processing apparatus 100 may be a substrate processing apparatus that performs thermal processing by supplying the modifying gas from the gas supply pipe 23 to the substrate W in the processing container 1 heated to a desired temperature.

Further, the substrate processing apparatus 100 shown in FIG. 1 has been described as including configurations (the gas supply pipe 23, a plasma generator 30 to be described later, etc.) for supplying the modifying gas and/or the active species of the modifying gas into the processing container 1, but is not limited thereto. In the substrate processing apparatus 100 that does not perform processing using the modifying gas and/or the active species of the modifying gas, these configurations (the gas supply pipe 23, the plasma generator 30 to be described later, etc.) may be omitted.

A purge gas is supplied to the gas supply pipe 24 from a purge gas supply source (not shown) via a gas pipe. A flow rate controller (not shown) and an opening/closing valve (not shown) are provided at the gas pipe (not shown). Thus, the purge gas from the purge gas supply source is supplied into the processing container 1 via the gas pipe and the gas supply pipe 24. As the purge gas, for example, an inert gas such as argon (Ar) or nitrogen (N₂) may be used. Although a case where the purge gas is supplied into the processing container 1 from the purge gas supply source through the gas pipe and the gas supply pipe 24 has been described, the present disclosure is not limited thereto, and the purge gas may be supplied from any of the gas supply pipes 21 to 23.

The plasma generator 30 is formed on a portion of a sidewall of the processing container 1. The plasma generator 30 turns the modifying gas into plasma to generate the active species (ions, radicals, etc.) of the modifying gas.

The plasma generator 30 includes a plasma partition wall 32, a pair of plasma electrodes 33 (one being shown in FIG. 1), a power supply line 34, a radio-frequency power supply 35, and an insulating protective cover 36.

The plasma partition wall 32 is hermetically welded to an outer wall of the processing container 1. The plasma partition wall 32 is formed of, for example, quartz. The plasma partition wall 32 has a concave cross-section and covers an opening 31 formed at the sidewall of the processing container 1. The opening 31 is formed to be elongated in the vertical direction so as to cover all the substrates W supported by the wafer boat 5 in the vertical direction. The gas supply pipe 23 for discharging the modifying gas is disposed in an inner space, i.e., the plasma generation space, which is defined by the plasma partition wall 32 and communicates with the inside of the processing container 1.

The pair of plasma electrodes 33 (one being shown in FIG. 1) each has an elongated shape and is disposed facing each other along the vertical direction on outer surfaces of walls on both sides of the plasma partition wall 32. Each plasma electrode 33 is held by, for example, a holder (not shown) provided at a side surface of the plasma partition wall 32. The power supply line 34 is connected to a lower end of each plasma electrode 33.

The power supply line 34 electrically connects each plasma electrode 33 to the radio-frequency power supply 35. In the illustrated example, one end of the power supply line 34 is connected to the lower end of each plasma electrode 33, and the other end is connected to the radio-frequency power supply 35.

The radio-frequency power supply 35 is connected to the lower end of each plasma electrode 33 via the power supply line 34, and supplies radio-frequency power of, for example, 13.56 MHz to the pair of plasma electrodes 33. Thus, the radio-frequency power is applied to the plasma generation space defined by the plasma partition wall 32. The modifying gas discharged from the gas supply pipe 23 is turned into plasma in the plasma generation space to which the radio-frequency power is applied, and the active species of the modifying gas thus generated are supplied to the inside of the processing container 1 via the opening 31.

The insulating protective cover 36 is installed at an outside of the plasma partition wall 32 so as to cover the plasma partition wall 32. A coolant passage (not shown) is provided in an inner portion of the insulating protective cover 36, and the plasma electrode 33 is cooled by flowing a coolant such as cooled nitrogen (N₂) gas through the coolant passage. In addition, a shield (not shown) may be provided between the plasma electrode 33 and the insulating protective cover 36 so as to cover the plasma electrode 33. The shield is made of a good conductor such as a metal, and is grounded.

An exhaust port 40 for vacuum-exhausting the inside of the processing container 1 is provided at the sidewall of the processing container 1 facing the opening 31. The exhaust port 40 is formed to be elongated in the vertical direction to correspond to the wafer boat 5. An exhaust port cover member 41 having a U-shaped cross-section is installed at a portion of the processing container 1 corresponding to the exhaust port 40 so as to cover the exhaust port 40. The exhaust port cover member 41 extends upward along the sidewall of the processing container 1. An exhaust pipe 42 for exhausting the processing container 1 through the exhaust port 40 is connected to a lower portion of the exhaust port cover member 41. A pressure control valve 43 for controlling an internal pressure of the processing container 1 and an exhauster 44 including a vacuum pump are connected to the exhaust pipe 42, and the inside of the processing container 1 is exhausted by the exhauster 44 through the exhaust pipe 42.

In addition, a cylindrical heater 50 for heating the processing container 1 and the substrate W therein is provided so as to surround an outer periphery of the processing container 1.

In addition, the substrate processing apparatus 100 includes a controller 60. The controller 60 performs control of an operation of each part of the substrate processing apparatus 100, for example, control of supply and stop of each gas by opening/closing the opening/closing valves 21c to 23c, control of a gas flow rate by the flow rate controllers 21b to 23b, and control of exhaust by the exhauster 44. The controller 60 also performs control of on-off of the radio-frequency power by the radio-frequency power supply 35 and control of a temperature of the substrate W by the heater 50.

The controller 60 may be, for example, a computer, etc. In addition, a computer program for controlling the operation of each part of the substrate processing apparatus 100 is stored in a non-transitory computer-readable storage medium. The storage medium may be, for example, a flexible disk, a compact disc, a hard disk, a flash memory, a DVD, or the like.

### Film Forming Process according to First Embodiment

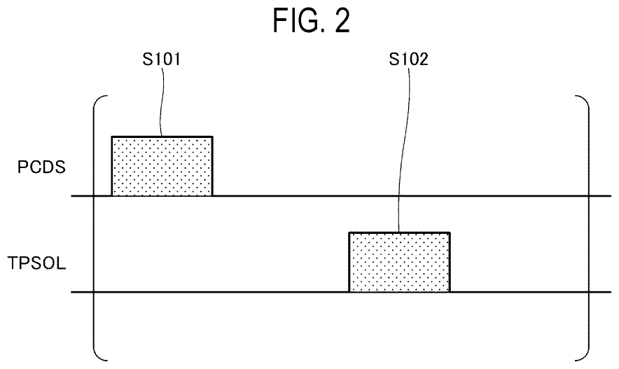

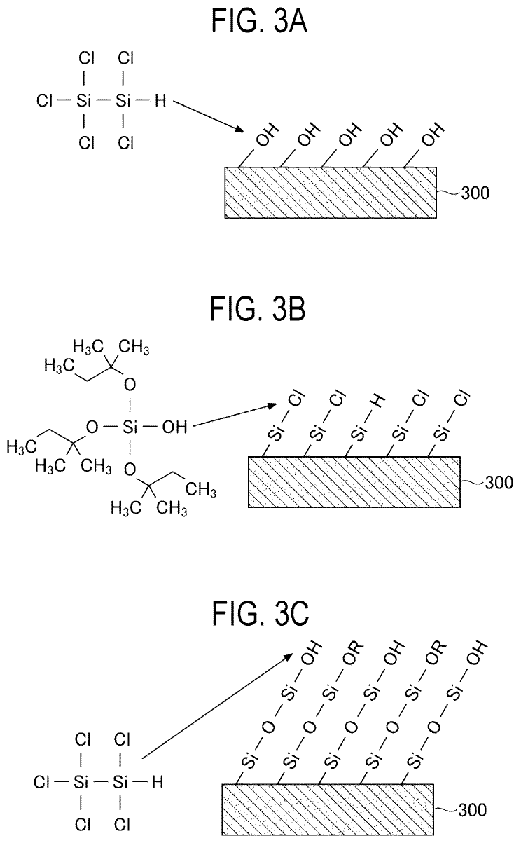

Next, an example of a film forming process by the substrate processing apparatus 100 is described. FIG. 2 is a time chart showing an example of a film forming process according to the first embodiment. FIGS. 3A to 3C are schematic diagrams showing examples of states of the substrate surface in the film forming process according to the first embodiment. Herein, an example is described in which PCDS is used as the first raw material gas and TPSOL is used as the second raw material gas to form a silicon oxide film on the surface of the substrate W (a surface of an underlayer 300).

The film forming process according to the first embodiment shown in FIG. 2 is a process in which one cycle including step S101 of supplying the first raw material gas (PCDS) and step S102 of supplying the second raw material gas (TPSOL) is repeated a plurality of times (a predetermined number of cycles) to form a silicon oxide film on the surface of the substrate W. In FIG. 2, one cycle is shown in parentheses. In addition, while the cycle is repeated, a N₂ gas, which is a purge gas, may be constantly (continuously) supplied from the gas supply pipe 24 during the film forming process.

First, the controller 60 prepares the substrate W. Specifically, the controller 60 controls the lift (not shown) to insert the wafer boat 5, on which the substrates W are placed, into the processing container 1. The controller 60 also controls the heater 50 to control the temperature of the substrate W in the processing container 1 to a predetermined processing temperature.

In step S101 of supplying the first raw material gas (PCDS), the controller 60 supplies the first raw material gas to the substrate W. Specifically, the controller 60 controls the pressure control valve 43 to control the internal pressure of the processing container 1 to a predetermined pressure. The controller 60 also controls the opening/closing valve 21c and the flow rate controller 21b to supply the first raw material gas at a predetermined flow rate for a predetermined time.

FIG. 3A is a schematic diagram showing an example of a state of the substrate surface at a start of the film forming process. In the example shown in FIG. 3A, the underlayer 300 of the substrate W is, for example, a silicon layer. (—OH) is formed at a termination on the surface of the substrate W (the underlayer 300). By supplying the first raw material gas to the substrate W, the first raw material gas reacts (e.g., dehydration-condenses) with (—OH) at the termination. As a result, as shown in FIG. 3B, the predetermined element (Si) of the first raw material gas is bonded to the surface of the substrate W, and (—Cl) and/or (—H) is formed at the termination.

In step S102 of supplying the second raw material gas (TPSOL), the controller 60 supplies the second raw material gas to the substrate W. Specifically, the controller 60 controls the pressure control valve 43 to control the internal pressure of the processing container 1 to a predetermined pressure. The controller 60 also controls the opening/closing valve 22c and the flow rate controller 22b to supply the second raw material gas at a predetermined flow rate for a predetermined time.

FIG. 3B is a schematic diagram showing an example of a state of the substrate surface at a start of the supply of the second raw material gas. (—Cl) and/or (—H) is formed at the termination on the surface of the substrate W (the underlayer 300). By supplying the second raw material gas to the substrate W, the second raw material gas reacts with hydrogen (H) and/or a halogen element (Cl) at the termination. As a result, as shown in FIG. 3C, the predetermined element (Si) and oxygen (O) of the second raw material gas are bonded to the surface of the substrate W, and (—OH) and/or (-R) is formed at the termination. Herein, R is a hydrocarbon group derived from TPSOL.

Then, in step S101 of supplying the first raw material gas (PCDS) in the next cycle, the controller 60 similarly supplies the first raw material gas to the substrate W.

FIG. 3C is a schematic diagram showing an example of a state of the substrate surface at a start of the supply of the first raw material gas in the next cycle. (—OH) and/or (-R) is formed at the termination on the surface of the substrate W (the underlayer 300). By supplying the first raw material gas to the substrate W, the first raw material gas reacts with (—OH) and/or (-R) at the termination. As a result, the predetermined element (Si) of the first raw material gas is bonded to the surface of the substrate W, and (—Cl) and/or (—H) is formed at the termination.

In this manner, the controller 60 repeats one cycle, including step S101 of supplying the first raw material gas (PCDS) and step S102 of supplying the second raw material gas (TPSOL), a plurality of times (a predetermined number of cycles) to form a silicon oxide film on the surface of the substrate W (the underlayer 300).

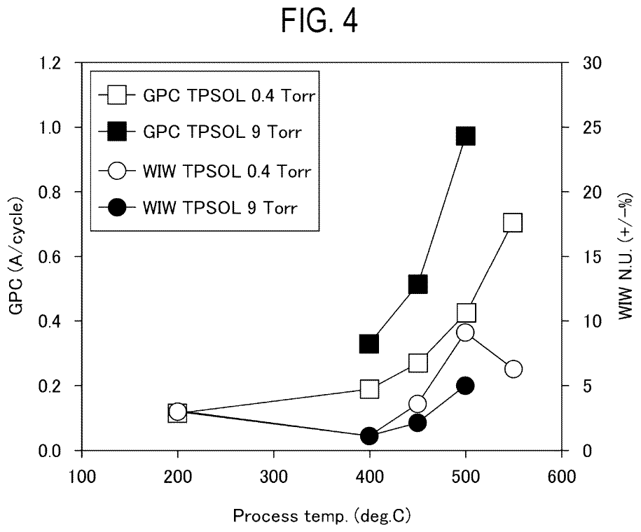

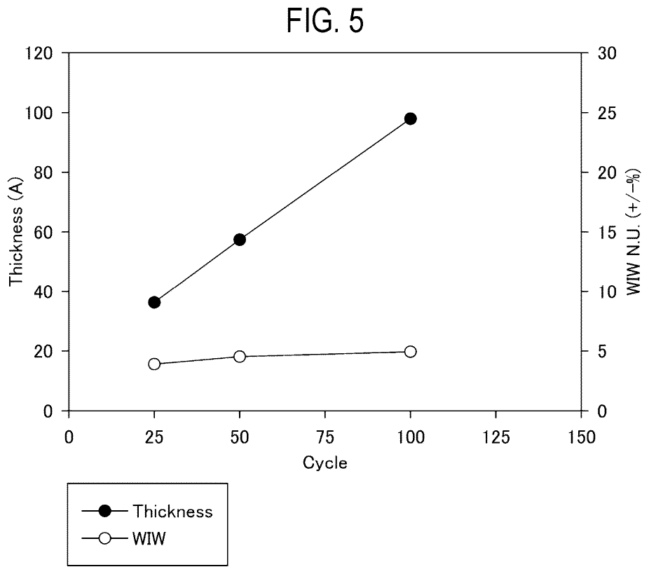

Next, examples of film formation results of the film forming process according to the first embodiment are described with reference to FIGS. 4 and 5.

FIG. 4 is a graph showing an example of a film formation rate and in-plane uniformity of a film thickness with respect to temperature and pressure. Herein, the film formation rate and the in-plane uniformity of the film thickness of a silicon oxide film were measured at a processing temperature (film formation temperature) in a range of 200 degrees C. to 550 degrees C. and at the internal pressure of the processing container 1 of 0.4 Torr or 9 Torr in step S102 of supplying the second raw material gas (TPSOL). In step S101 of supplying the first raw material gas (PCDS), the flow rate of the first raw material gas was set to 50 sccm, the supply time of the first raw material gas was set to 30 sec, and the internal pressure of the processing container 1 was set to 4 Torr. In step S102 of supplying the second raw material gas (TPSOL), the flow rate of the second raw material gas was set to 1 sccm, and the supply time of the second raw material gas was set to 30 sec. Herein, the cycle was repeated 100 times.

In the graph shown in FIG. 4, the horizontal axis represents the processing temperature (Process temp. (° C.)). The left vertical axis represents the film formation rate (GPC (Growth Per Cycle) (A/cycle)) which is an amount of a film formed per cycle. The right vertical axis represents the in-plane uniformity (WIW). The film formation rate GPC when the pressure in step S102 is set to 0.4 Torr is indicated by an open square. The film formation rate GPC when the pressure in step S102 is set to 9 Torr is indicated by a filled square. The in-plane uniformity WIW when the pressure in step S102 is set to 0.4 Torr is indicated by an open circle. The in-plane uniformity WIW when the pressure in step S102 is set to 9 Torr is indicated by a filled circle.

As shown in FIG. 4, the amount of film formed tends to increase as the film formation temperature increases. In addition, the film formation rate tends to increase depending on the pressure in step S102 of supplying the second raw material gas (TPSOL).

FIG. 5 is a graph showing an example of the film thickness and the in-plane uniformity of the film thickness with respect to the number of cycles. The film thickness and the in-plane uniformity of the film thickness of the silicon oxide film were measured when the number of cycles was 25, 50, and 100. The processing temperature (the film formation temperature) was set to 500 degrees C. In step S101 of supplying the first raw material gas (PCDS), the flow rate of the first raw material gas was set to 50 sccm, the supply time of the first raw material gas was set to 30 sec, and the internal pressure of the processing container 1 was set to 4 Torr. In step S102 of supplying the second raw material gas (TPSOL), the flow rate of the second raw material gas was set to 1 sccm, the supply time of the second raw material gas was set to 30 sec, and the internal pressure of the processing container 1 was set to 9 Torr.

In the graph shown in FIG. 5, the horizontal axis represents the number of cycles (Cycle). The left vertical axis represents the film thickness (Thickness (A)) of the silicon oxide film. The right vertical axis represents the in-plane uniformity (WIW). The film thickness (Thickness) is indicated by a filled circle. The in-plane uniformity WIW is indicated by an open circle.

As shown in FIG. 5, in the film forming process according to the first embodiment (see FIG. 2), the film thickness tends to increase linearly with the number of cycles. In addition, even when the number of cycles increases, the in-plane uniformity tends to be sufficiently small.

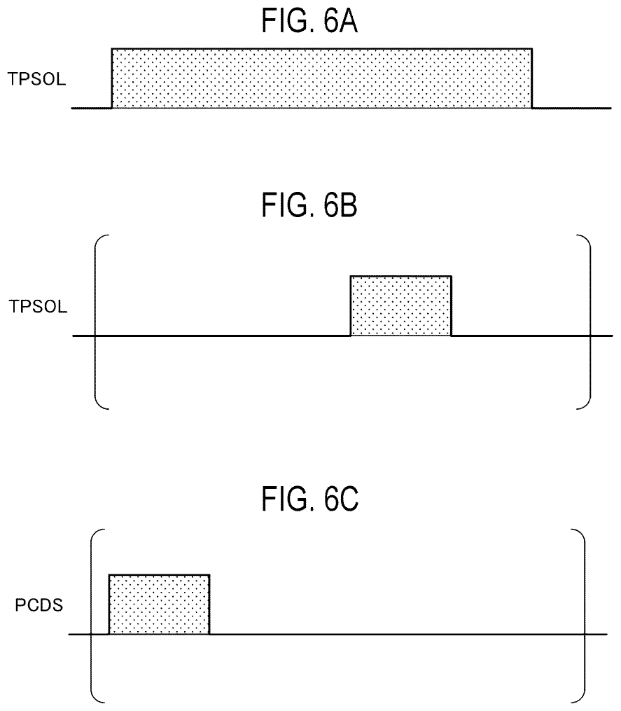

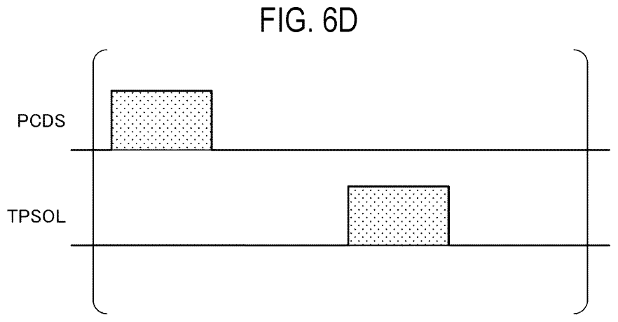

Next, an example of a film formation result of the film forming process according to the first embodiment is described with reference to FIGS. 6A to 8, in comparison with film forming processes according to first to third reference examples.

FIG. 6A is a time chart showing an example of the film forming process according to the first reference example. The film forming process according to the first reference example is a film forming process of continuously supplying only TPSOL.

FIG. 6B is a time chart showing an example of the film forming process according to the second reference example. The film forming process according to the second reference example is a film forming process of intermittently (discontinuously) supplying only TPSOL. In other words, it is a film forming process of performing only step S102 of supplying the second raw material gas in the film forming process according to the first embodiment (see FIGS. 2 and 6D).

FIG. 6C is a time chart showing an example of the film forming process according to the third reference example. The film forming process according to the third reference example is a film forming process of intermittently (discontinuously) supplying only PCDS. In other words, it is a film forming process of performing only step S101 of supplying the first raw material gas in the film forming process according to the first embodiment (see FIGS. 2 and 6D).

FIG. 6D is a time chart showing an example of the film forming process according to the first embodiment. In the film forming process according to the first embodiment (see also FIG. 2), step S101 of supplying the first raw material gas (PCDS) and step S102 of supplying the second raw material gas (TPSOL) are alternately repeated.

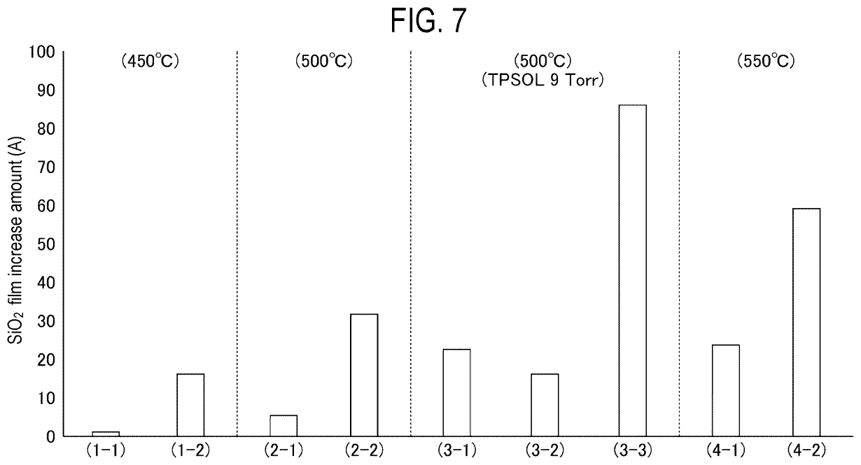

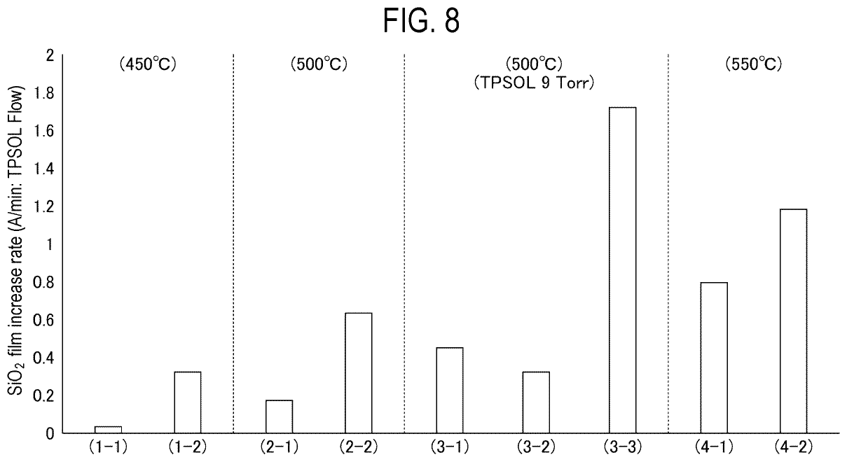

FIG. 7 is a graph showing an example of a film increase amount (A) of a SiO₂ film in each film forming process. FIG. 8 is a graph showing an example of a film increase rate (A/min) of the SiO₂ film in each film forming process. Herein, FIG. 8 shows a value obtained by dividing the film increase amount detected in FIG. 7 by a total supply time of TPSOL. Since TPSOL is not supplied in (3-2), this value is a value obtained by dividing the film increase amount by the total supply time of TPSOL in (3-1) and (3-3).

In (1-1), in the film forming process according to the first reference example shown in FIG. 6A, the film forming process was performed with the processing temperature of 450 degrees C. and with the flow rate of 1 sccm, the supply time of 30 min, and the pressure of 0.5 Torr in the TPSOL supplying step.

In (1-2), in the film forming process according to the first embodiment shown in FIG. 6D, the film forming process was performed by repeating 100 cycles under the processing temperature of 450 degrees C., with the flow rate of 50 sccm, the supply time of 30 sec, and the pressure of 4 Torr in the PCDS supplying step, and with the flow rate of 1 sccm, the supply time of 30 sec, and the pressure of 0.5 Torr in the TPSOL supplying step. The total supply time of TPSOL was 50 min.

In (2-1), in the film forming process according to the first reference example shown in FIG. 6A, the film forming process was performed with the processing temperature of 500 degrees C. and with the flow rate of 1 sccm, the supply time of 30 min, and the pressure of 0.5 Torr in the TPSOL supplying step.

In (2-2), in the film forming process according to the first embodiment shown in FIG. 6D, the film forming process was performed by repeating 100 cycles under the processing temperature of 500 degrees C., with the flow rate of 50 sccm, the supply time of 30 sec, and the pressure of 4 Torr in the PCDS supplying step, and with the flow rate of 1 sccm, the supply time of 30 sec, and the pressure of 0.5 Torr in the TPSOL supplying step. The total supply time of TPSOL was 50 min.

In (3-1), in the film forming process according to the second reference example shown in FIG. 6B, the film forming process was performed by repeating 100 cycles with the processing temperature of 500 degrees C. and with the flow rate of 1 sccm, the supply time of 30 sec, and the pressure of 9 Torr in the TPSOL supplying step. The total supply time of TPSOL was 50 min.

In (3-2), in the film forming process according to the third reference example shown in FIG. 6C, the film forming process was performed by repeating 100 cycles with the processing temperature of 500 degrees C. and with the flow rate of 50 sccm, the supply time of 30 sec, and the pressure of 4 Torr in the PCDS supplying step.

In (3-3), in the film forming process according to the first embodiment shown in FIG. 6D, the film forming process was performed by repeating 100 cycles under the processing temperature of 500 degrees C., with the flow rate of 50 sccm, the supply time of 30 sec, and the pressure of 4 Torr in the PCDS supplying step, and with the flow rate of 1 sccm, the supply time of 30 sec, and the pressure of 9 Torr in the TPSOL supplying step. The total supply time of TPSOL was 50 min.

In (4-1), in the film forming process according to the first reference example shown in FIG. 6A, the film forming process was performed with the processing temperature of 550 degrees C. and with the flow rate of 1 sccm, the supply time of 30 min, and the pressure of 0.5 Torr in the TPSOL supplying step.

In (4-2), in the film forming process according to the first embodiment shown in FIG. 6D, the film forming process was performed by repeating 100 cycles under the processing temperature of 550 degrees C., with the flow rate of 50 sccm, the supply time of 30 sec, and the pressure of 4 Torr in the PCDS supplying step, and with the flow rate of 1 sccm, the supply time of 30 sec, and the pressure of 0.5 Torr in the TPSOL supplying step. The total supply time of TPSOL was 50 min.

As shown by comparing (1-1) and (1-2), at the processing temperature of 450 degrees C., the film forming process according to the first embodiment (see FIG. 6D) has a higher film increase rate than the film forming process according to the first reference example (see FIG. 6A).

In addition, as shown by comparing (2-1) and (2-2), at the processing temperature of 500degrees C., the film forming process according to the first embodiment (see FIG. 6D) has a higher film increase rate than the film forming process according to the first reference example (see FIG. 6A).

In addition, as shown by comparing (4-1) and (4-2), at the processing temperature of 550degrees C., the film forming process according to the first embodiment (see FIG. 6D) has a higher film increase rate than the film forming process according to the first reference example (see FIG. 6A).

That is, at any processing temperature of 450 degrees C. to 550 degrees C., the film increase rate of the film forming process according to the first embodiment (see FIG. 6D) in which PCDS and TPSOL are alternately supplied is higher than that of the film forming process according to the first reference example (see FIG. 6A) in which TPSOL is supplied alone.

In addition, as shown by comparing (3-1) and (3-3), the film forming process according to the first embodiment (see FIG. 6D) has a higher film increase rate than the film forming process according to the second reference example (see FIG. 6B). In addition, as shown by comparing (3-2) and (3-3), the film forming process according to the first embodiment (see FIG. 6D) has a higher film increase rate than the film forming process according to the third reference example (see FIG. 6C).

In addition, the film forming process according to the first embodiment (see FIG. 6D) shown in (3-3) has a higher film increase rate than a total value of the film forming process according to the second reference example (see FIG. 6B) shown in (3-1) and the film forming process according to the third reference example (see FIG. 6C) shown in (3-2).

That is, even if the total amount of PCDS and TPSOL supplied into the processing container 1 is the same, by alternately supplying PCDS and TPSOL to form a silicon oxide film, the film increase amount of the silicon oxide film is increased compared to a case where one raw material gas (PCDS) is first supplied and then the other raw material gas (TPSOL) is supplied to form a silicon oxide film.

As described above, according to the film forming process according to the first embodiment, it is possible to form a silicon oxide film without using a strong oxidizing source. This makes it possible to suppress damage to the underlayer 300 caused by a strong oxidizing source such as an oxidizing gas. For example, if the underlayer 300 is a Low-k film or the like containing carbon (C), the carbon (C) in the underlayer 300 may be reduced by the oxidizing gas. In contrast, with the film forming process according to the first embodiment, it is possible to suppress the reduction in carbon (C) in the underlayer 300. This makes it possible to prevent a dielectric constant of the underlayer 300, which functions as a Low-k film, from increasing.

In addition, with the film forming process according to the first embodiment, it is possible to form a silicon oxide film without using plasma. This makes it possible to suppress damage to the underlayer 300 caused by plasma.

In addition, with the film forming process according to the first embodiment, it is possible to form a silicon oxide film with good step coverage.

In addition, with the film forming process according to the first embodiment, it is possible to form a silicon oxide film without using a metal catalyst. This makes it possible to prevent metal elements, which are derived from the metal catalyst, from being mixed into the silicon oxide film.

### Film Forming Process according to Second Embodiment

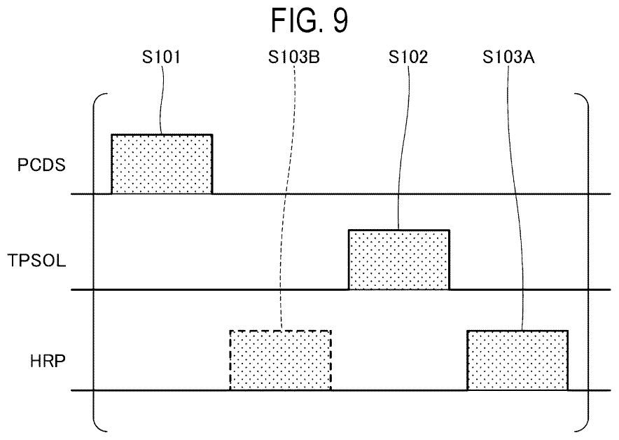

Next, another example of the film forming process by the substrate processing apparatus 100 is described. FIG. 9 is a time chart showing an example of a film forming process of a second embodiment. Herein, an example is described in which PCDS is used as the first raw material gas and TPSOL is used as the second raw material gas to form a silicon oxide film on the surface of the substrate W (the surface of the underlayer 300).

The film forming process according to the second embodiment shown in FIG. 9 is a process in which one cycle including step S101 of supplying the first raw material gas (PCDS), step S102 of supplying the second raw material gas (TPSOL), and step S103 (S103A and S103B) of modifying the surface of the substrate W by using a modifying gas is repeated a plurality of times (a predetermined number of cycles) to form a silicon oxide film on the surface of the substrate W. In FIG. 9, one cycle is shown in parentheses. In addition, while the cycle is repeated, a N₂ gas, which is a purge gas, may be constantly (continuously) supplied from the gas supply pipe 24 during the film forming process.

First, the controller 60 prepares the substrate W. Specifically, the controller 60 controls the lift (not shown) to insert the wafer boat 5, on which the substrates W are placed, into the processing container 1. The controller 60 also controls the heater 50 to control the temperature of the substrate W in the processing container 1 to a predetermined processing temperature.

In step S101 of supplying the first raw material gas (PCDS), the controller 60 supplies the first raw material gas to the substrate W. Specifically, the controller 60 controls the pressure control valve 43 to control the internal pressure of the processing container 1 to a predetermined pressure. The controller 60 also controls the opening/closing valve 21c and the flow rate controller 21b to supply the first raw material gas at a predetermined flow rate for a predetermined time.

In step S102 of supplying the second raw material gas (TPSOL), the controller 60 supplies the second raw material gas to the substrate W. Specifically, the controller 60 controls the pressure control valve 43 to control the internal pressure of the processing container 1 to a predetermined pressure. The controller 60 also controls the opening/closing valve 22c and the flow rate controller 22b to supply the second raw material gas at a predetermined flow rate for a predetermined time.

In step S103A of modifying the surface of the substrate W by using the modifying gas, the controller 60 supplies the active species of the modifying gas to the substrate W. Specifically, the controller 60 controls the pressure control valve 43 to control the internal pressure of the processing container 1 to a predetermined pressure. The controller 60 also controls the opening/closing valve 23c and the flow rate controller 23b to supply the modifying gas (e.g., a H₂ gas) at a predetermined flow rate for a predetermined time. Then, the controller 60 controls the radio-frequency power supply 35 to generate plasma. As a result, the active species of the modifying gas are supplied to the substrate W.

In this manner, the controller 60 repeats one cycle, including step S101 of supplying the first raw material gas (PCDS), step S102 of supplying the second raw material gas (TPSOL), and step S103A of modifying the surface of the substrate W by using the modifying gas, a plurality of times (a predetermined number of cycles) to form a silicon oxide film on the surface of the substrate W (the underlayer 300).

Step S103A of modifying the surface of the substrate W by using the modifying gas has been described as being performed after step S102 of supplying the second raw material gas (TPSOL) and before step S101 of supplying the next first raw material gas (PCDS), but the present disclosure is not limited thereto.

Step S103B of modifying the surface of the substrate W by using a modifying gas may be configured to be performed after step S101 of supplying the first raw material gas (PCDS) and before step S102 of supplying the next second raw material gas (TPSOL). In addition, both steps S103A and S103B of modifying the surface of the substrate W using the modifying gas may be performed in one cycle.

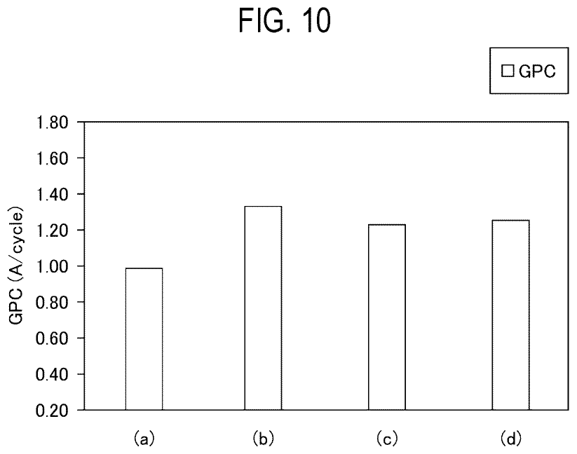

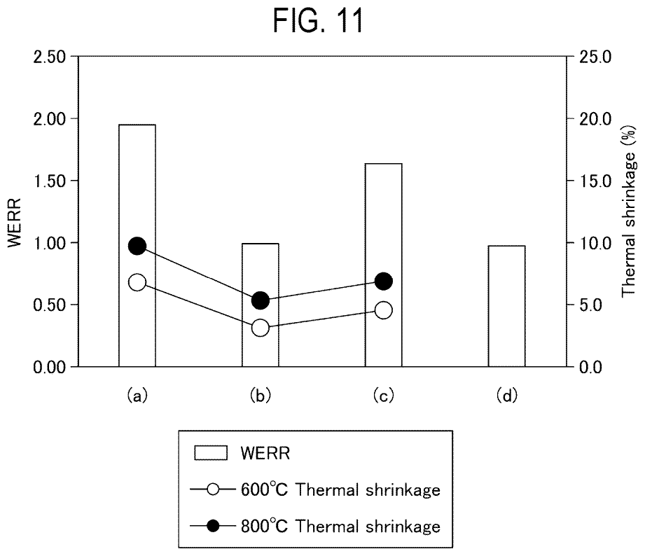

Next, examples of film formation results of the film forming process according to the second embodiment are described with reference to FIGS. 10 and 11.

FIG. 10 is a graph showing an example of a film formation rate GPC. Herein, a silicon oxide film was formed by processes (a) to (d) to be described later. The processing temperature (film formation temperature) was set to 500 degrees C. In step S101 of supplying the first raw material gas (PCDS), the flow rate of the first raw material gas was set to 50 sccm, the supply time of the first raw material gas was set to 30 sec, and the internal pressure of the processing container 1 was set to 4 Torr. In step S102 of supplying the second raw material gas (TPSOL), the flow rate of the second raw material gas was set to 1 sccm, the supply time of the second raw material gas was set to 30 sec, and the internal pressure of the processing container 1 was set to 9 Torr. In steps S103A and S103B (HRP) of modifying the surface of the substrate W by using hydrogen plasma, a flow rate of a H₂ gas was set to 2,000 sccm, a supply time of the H₂ gas was set to 30 to 60 sec, the internal pressure of the processing container 1 was set to 0.1 Torr, and the RF power was set to 100 W. In addition, the cycle was repeated 100 times.

In (a), a silicon oxide film is formed by repeating one cycle a plurality of times (herein, 100 cycles), the one cycle including step S101 of supplying the first raw material gas (PCDS) and step S102 of supplying the second raw material gas (TPSOL) in this order without performing a step of supplying hydrogen plasma. That is, (a) corresponds to the film forming process according to the first embodiment.

In (b), a silicon oxide film is formed by repeating one cycle a plurality of times (herein, 100 cycles), the one cycle including step S101 of supplying the first raw material gas (PCDS), step S102 of supplying the second raw material gas (TPSOL), and step S103A of supplying the hydrogen plasma in this order. In (b), step S103A of supplying the hydrogen plasma lasts for 30 sec.

In (c), a silicon oxide film is formed by repeating one cycle a plurality of times (herein, 100 cycles), the one cycle including step S101 of supplying the first raw material gas (PCDS), step S103B of supplying the hydrogen plasma, and step S102 of supplying the second raw material gas (TPSOL) in this order. In (c), step S103B of supplying the hydrogen plasma lasts for 30 sec.

In (d), a silicon oxide film is formed by repeating one cycle a plurality of times (herein, 100 cycles), the one cycle including step S101 of supplying the first raw material gas (PCDS), step S103B of supplying the hydrogen plasma, and step S102 of supplying the second raw material gas (TPSOL) in this order. In (d), step S103B of supplying the hydrogen plasma lasts for 60 sec.

As shown in FIG. 10, by adding steps S103A and S103B of supplying the hydrogen plasma (see (b) to (d)), the film formation rate is increased compared to a case where a step of supplying the hydrogen plasma is not performed (see (a)).

In addition, as shown by comparing (b) with (c) and (d), the film formation rate is improved by performing step S103A of supplying the hydrogen plasma after step S102 of supplying the second raw material gas (TPSOL).

FIG. 11 is a graph showing an example of a wet etching rate and thermal shrinkage due to heat treatment. Herein, the wet etching rate (WERR) is shown in a bar graph under etching conditions for wet etching a laminated film in which SiO₂ films and SiN films are alternately laminated for the silicon oxide film formed in (a) to (d). In addition, the thermal shrinkage of the silicon oxide film when the substrate W is heat-treated at 600 degrees C. or 800 degrees C. in a N₂ atmosphere for 30 minutes is shown in a line graph. The case where the substrate W is heat-treated at 600 degrees C. is indicated by an open circle, and the case where the substrate W is heat-treated at 800 degrees C. is indicated by a filled circle.

As shown in FIG. 11, by adding steps S103A and S103B of supplying the hydrogen plasma (see (b) to (d)), etching resistance is improved compared to a case where the step of supplying the hydrogen plasma is not performed (see (a)). In addition, by adding steps S103A and S103B of supplying the hydrogen plasma (see (b) and (c)), a shrinkage rate during heat treatment is reduced compared to the case where the step of supplying the hydrogen plasma is not performed (see (a)).

In addition, as shown by comparing (b) with (c) and (d), by performing step S103A of supplying the hydrogen plasma after step S102 of supplying the second raw material gas (TPSOL), the etching resistance is improved and the shrinkage rate during heat treatment is reduced.

As described above, with the film forming process according to the second embodiment, it is possible to improve the film formation rate and film quality by removing unnecessary functional groups, which reduce reactivity, from the surface of the substrate W by the hydrogen plasma.

### Film Forming Process according to Third Embodiment

In the film forming processes according to the first and second embodiments, an example has been described in which PCDS, which is a chlorosilane-based gas, is used as the first raw material gas and TPSOL, which is a silanol-based gas, is used as the second raw material gas, but the present disclosure is not limited thereto.

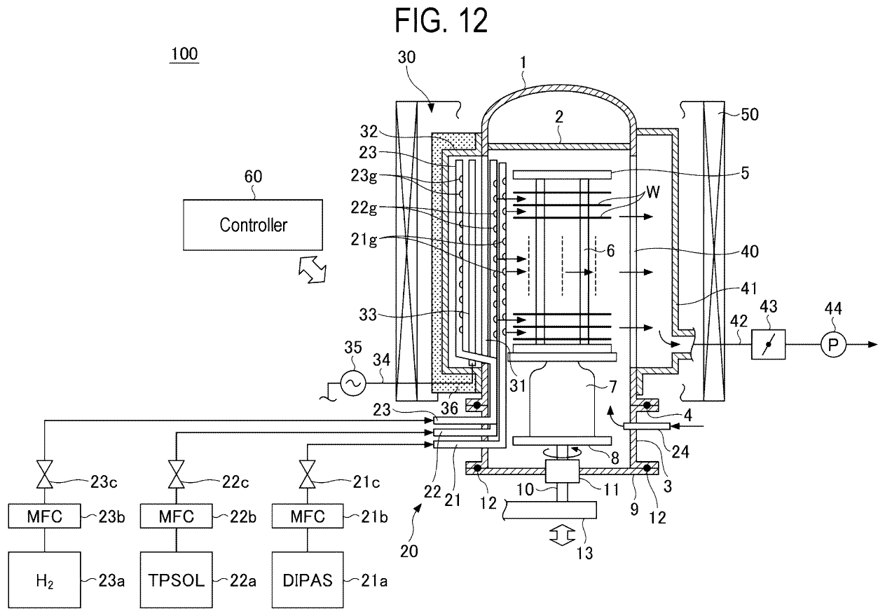

FIG. 12 is a schematic diagram showing an example of a configuration of a substrate processing apparatus 100 according to a third embodiment. The substrate processing apparatus 100 according to the third embodiment has a first raw material gas different from the substrate processing apparatus 100 according to the first embodiment.

The gas supply source 21a supplies a first raw material gas containing a predetermined element. Herein, an example is described in which the first raw material gas is an aminosilane-based gas.

Specifically, the first raw material gas may be 3DMAS (Trisdimethylaminosilane). The chemical formula of 3DMAS is shown below.

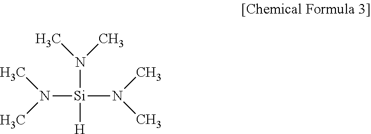

The first raw material gas may also be DIPAS (Diisopropylaminosilane). The chemical formula of DIPAS is shown below. In the following description, an example is described in which the first raw material gas is DIPAS.

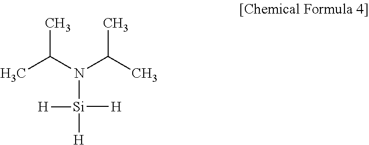

### Film Forming Process according to Third Embodiment

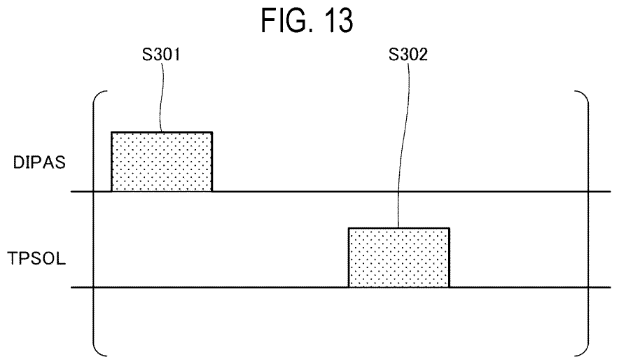

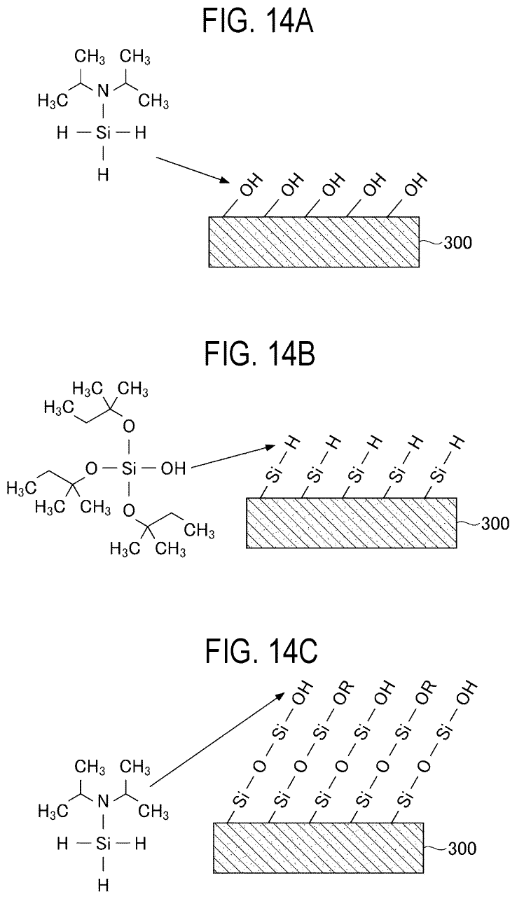

Next, an example of a film forming process using the substrate processing apparatus 100 is described. FIG. 13 is a time chart showing an example of the film forming process according to the third embodiment. FIGS. 14A to 14C are schematic diagrams showing examples of states of the substrate surface in the film forming process according to the third embodiment. Herein, an example is described in which DIPAS is used as the first raw material gas and TPSOL is used as the second raw material gas to form a silicon oxide film on the surface of the substrate W (the surface of the underlayer 300).

The film forming process according to the third embodiment shown in FIG. 13 is a process in which one cycle including step S301 of supplying the first raw material gas (DIPAS) and step S302 of supplying the second raw material gas (TPSOL) is repeated a plurality of times (a predetermined number of cycles) to form a silicon oxide film on the surface of the substrate W. In FIG. 13, one cycle is shown in parentheses. In addition, while the cycle is repeated, a N₂ gas, which is a purge gas, may be constantly (continuously) supplied from the gas supply pipe 24 during the film forming process.

First, the controller 60 prepares the substrate W. Specifically, the controller 60 controls the lift (not shown) to insert the wafer boat 5, on which the substrates W are placed, into the processing container 1. The controller 60 also controls the heater 50 to control the temperature of the substrate W in the processing container 1 to a predetermined processing temperature.

In step S301 of supplying the first raw material gas (DIPAS), the controller 60 supplies the first raw material gas to the substrate W. Specifically, the controller 60 controls the pressure control valve 43 to control the internal pressure of the processing container 1 to a predetermined pressure. The controller 60 also controls the opening/closing valve 21c and the flow rate controller 21b to supply the first raw material gas at a predetermined flow rate for a predetermined time.

FIG. 14A is a schematic diagram showing an example of a state of the substrate surface at a start of the film forming process. In the example shown in FIG. 14A, the underlayer 300 of the substrate W is, for example, a silicon layer. (—OH) is formed at a termination on the surface of the substrate W (the underlayer 300). By supplying the first raw material gas to the substrate W, the first raw material gas reacts (e.g., dehydration-condenses) with (—OH) at the termination. As a result, as shown in FIG. 14B, the predetermined element (Si) of the first raw material gas is bonded to the surface of the substrate W, and (—H) is formed at the termination.

In step S302 of supplying the second raw material gas (TPSOL), the controller 60 supplies the second raw material gas to the substrate W. Specifically, the controller 60 controls the pressure control valve 43 to control the internal pressure of the processing container 1 to a predetermined pressure. The controller 60 also controls the opening/closing valve 22c and the flow rate controller 22b to supply the second raw material gas at a predetermined flow rate for a predetermined time.

FIG. 14B is a schematic diagram showing an example of a state of the substrate surface at a start of the supply of the second raw material gas. (—H) is formed at the termination on the surface of the substrate W (the underlayer 300). By supplying the second raw material gas to the substrate W, the second raw material gas reacts with hydrogen (H) at the termination. As a result, as shown in FIG. 14C, the predetermined element (Si) and oxygen (O) of the second raw material gas are bonded to the surface of the substrate W, and (—OH) and/or (-R) is formed at the termination. Herein, R is a hydrocarbon group derived from TPSOL.

Then, in step S301 of supplying the first raw material gas (DIPAS) in the next cycle, the controller 60 similarly supplies the first raw material gas to the substrate W.

FIG. 14C is a schematic diagram showing an example of a state of the substrate surface at a start of the supply of the first raw material gas in the next cycle. (—OH) and/or (-R) is formed at the termination on the surface of the substrate W (the underlayer 300). By supplying the first raw material gas to the substrate W, the first raw material gas reacts with (—OH) and/or (-R) at the termination. As a result, the predetermined element (Si) of the first raw material gas is bonded to the surface of the substrate W, and (—H) is formed at the termination.

In this manner, the controller 60 repeats one cycle, including step S301 of supplying the first raw material gas (DIPAS) and step S302 of supplying the second raw material gas (TPSOL), a plurality of times (a predetermined number of cycles) to form a silicon oxide film on the surface of the substrate W (the underlayer 300).

In addition, in the film forming process according to the third embodiment (see FIG. 13), a step of modifying the surface of the substrate W by using a modifying gas (see S103A and S103B in FIG. 9) may be added, as in the film forming process according to the second embodiment.

In addition, in the film forming processes according to the first to third embodiments, an example has been described in which a silicon oxide film is formed, but the present disclosure is not limited thereto. The oxide film formed may be SiO₂, SiON, SiCON, or the like.

In addition, in the film forming process according to the first to third embodiments, an example has been described in which the predetermined element is silicon (Si), but the predetermined element may be a metal element (e.g., Ge, B, Al, Hf, Zr, Ta, La, Ti, etc.). In this case, it is desirable that the first raw material gas is a halide of the predetermined element. Specifically, the first raw material gas may be a chloride such as GeCl₄, BCl₃, AlCl₃, HfCl₄, ZrCl₄, TaCl₅, or LaCl₃. In addition, the first raw material gas may contain an organic functional group or a hydrogenated bond. In addition, it is desirable that the second raw material gas is a hydroxide of the predetermined element. Specifically, the second raw material gas may be a hydroxide such as B(OH)₃, Zr(OH)₄, Al(OH)₃, or La(OH)₃. In addition, the second raw material gas may contain an organic functional group or a halogen.

In addition, the second raw material gas may be formed by supplying hydrogen radicals to a metal alkoxide to change into a form containing a hydroxyl group. For example, the second raw material gas containing a hydroxyl group may be formed by supplying a metal alkoxide gas from the gas supply pipe 21 into the processing container 1, generating plasma of a hydrogen gas, which is supplied from the gas supply pipe 23, in the plasma generator 30, and reacting the metal alkoxide gas with the hydrogen radicals in the processing container 1. Examples of such a metal alkoxide may include Ge(OCH(CH₃)₂)₄, Ti[OC(CH₃)₃]₄, Zr[OC(CH₃)₃]₄, Hf[OC(CH₃)₃]₄, and Ta(OC₂H₅)₅.

The film forming method of the present embodiments (the first to third embodiments) using the substrate processing apparatus 100 has been described above, but the present disclosure is not limited to the above-described embodiments and the like, and various modifications and improvements are possible within the scope of the gist of the present disclosure described in the claims.

The substrate processing apparatus 100 performing the film forming process has been described as a vertical substrate processing apparatus that processes a number of substrates W placed in multiple stages as shown in FIG. 1, but the substrate processing apparatus 100 is not limited thereto. The substrate processing apparatus 100 may be a single-wafer type substrate processing apparatus or a semi-batch type substrate processing apparatus. In addition, the above-described film forming process may be applied to a single-wafer type substrate processing apparatus that processes a single substrate mounted on a mounting table. In addition, the above-described film forming process may be applied to a semi-batch type substrate processing apparatus that processes a plurality of substrates mounted on a mounting table.

According to the present disclosure in some embodiments, it is possible to provide a film forming method and a substrate processing apparatus for forming an oxide film containing a predetermined element and oxygen on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method of forming an oxide film, which contains at least a predetermined element and oxygen, on a substrate, comprising:
(a) supplying a first raw material gas, which contains the predetermined element, to the substrate;
(b) supplying a second raw material gas, which contains the predetermined element, contains a bond between the predetermined element and oxygen and a bond between the predetermined element and a hydroxyl group, and is different from the first raw material gas, to the substrate; and
(c) repeating one cycle a plurality of times, the one cycle including (a) and (b).

2. The film forming method of claim 1, further comprising:
(d) supplying a modifying gas, which modifies a surface of the substrate, to the substrate.

3. The film forming method of claim 2, wherein in (d), plasma of the modifying gas is supplied to the substrate.

4. The film forming method of claim 2, wherein the modifying gas includes at least one selected from the group of a hydrogen-containing gas, an oxygen-containing gas, and a nitrogen-containing gas.

5. The film forming method of claim 2, wherein (c) includes repeating (a), (b), and (d) sequentially a plurality of times.

6. The film forming method of claim 1, wherein the predetermined element includes at least one selected from the group of Si, Ge, B, Al, Hf, Zr, Ta, La, and Ti.

7. The film forming method of claim 1, wherein the predetermined element is Si, and
wherein the first raw material gas contains at least one selected from the group of a bond between the predetermined element and hydrogen, a bond between the predetermined element and a halogen element, and a bond between the predetermined element and nitrogen.

8. The film forming method of claim 1, wherein the predetermined element is Si, and
wherein the first raw material gas includes at least one selected from the group of a silane-based gas, a chlorosilane-based gas, and a silylamine-based gas.

9. The film forming method of claim 1, wherein the second raw material gas is a silanol-based gas.

10. The film forming method of claim 1, wherein the predetermined element is a metal element,
wherein the first raw material gas is a halide of the metal element, and
wherein the second raw material gas is a hydroxide of the metal element.

11. The film forming method of claim 1, wherein the predetermined element is a metal element,
wherein the first raw material gas is a halide of the metal element, and
wherein the second raw material gas is formed by supplying hydrogen radicals to a metal alkoxide containing the metal element.

12. A substrate processing apparatus comprising:
a processing container;
a substrate support that supports a substrate within the processing container;
a first raw material gas supply that supplies a first raw material gas containing a predetermined element into the processing container;
a second raw material gas supply that supplies a second raw material gas, which contains the predetermined element, contains a bond between the predetermined element and oxygen and a bond between the predetermined element and a hydroxyl group, and is different from the first raw material gas, into the processing container; and
a controller configured to be capable of performing a process including:
(a) supplying the first raw material gas, which contains the predetermined element, to the substrate;
(b) supplying the second raw material gas, which contains the predetermined element, contains the bond between the predetermined element and oxygen and the bond between the predetermined element and the hydroxyl group, and is different from the first raw material gas, to the substrate; and
(c) repeating one cycle a plurality of times, the one cycle including (a) and (b).
